(19) United States
(12) Patent Application Publication
(10) Pub. No.: US 2025/0234624 A1
(43) Pub. Date: Jul. 17, 2025

(54) SEMICONDUCTOR DEVICE

(71) Applicant: SAMSUNG ELECTRONICS CO., LTD., Suwon-si (KR)

(72) Inventors: Sungnam Lyu, Suwon-si (KR); Eunmi Kim, Suwon-si (KR); Hyojung Noh, Suwon-si (KR); Nayoung Lee, Suwon-si (KR); Eulji Jeong, Suwon-si (KR)

(21) Appl. No.: 18/825,478

(22) Filed: Sep. 5, 2024

(30) Foreign Application Priority Data
Jan. 12, 2024 (KR) 10-2024-0005437

(51) Int. Cl. H01L 29/423

(52) U.S. Cl. CPC H10D 64/518; H10D 64/512

(57) ABSTRACT

An example semiconductor device includes a channel structure, a gate insulating layer on the channel structure, and a first electrode portion and a second electrode portion on the gate insulating layer. The first electrode portion includes a lower portion, which contacts the gate insulating layer, and an upper portion, which is spaced apart from the gate insulating layer. The second electrode portion includes a first lower portion and a second lower portion. The first lower portion of the second electrode portion is between the gate insulating layer and the upper portion of the first electrode portion, and the upper portion of the first electrode portion is between the first and second lower portions of the second electrode portion.

### CROSS-REFERENCE TO RELATED APPLICATION

This application claims priority under 35 U.S.C. § 119 to Korean Patent Application No. 10-2024-0005437, filed on Jan. 12, 2024, in the Korean Intellectual Property Office, the entire contents of which are hereby incorporated by reference.

### BACKGROUND

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices can also benefit from high operating speeds and/or low operating voltages, and thus, it is desired to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

The present disclosure relates to a semiconductor device with improved electric characteristics and an increased integration density.

In some implementations, a semiconductor device may include a channel structure, a gate insulating layer on the channel structure, and a first electrode portion and a second electrode portion on the gate insulating layer. The first electrode portion may include a lower portion, which is in contact with the gate insulating layer, and an upper portion, which is spaced apart from the gate insulating layer. The second electrode portion may include a first lower portion and a second lower portion. The first lower portion of the second electrode portion may be provided between the gate insulating layer and the upper portion of the first electrode portion, and the upper portion of the first electrode portion may be provided between the first and second lower portions of the second electrode portion.

In some implementations, a semiconductor device may include a channel structure, a first gate insulating layer on the channel structure, and a first gate electrode on the first gate insulating layer. The first gate electrode may include a top surface and a bottom surface, which are spaced apart from each other in a first direction, and the first gate electrode may include a first electrode portion and a second electrode portion on the first electrode portion. A mean length of grains of the first electrode portion in the first direction may be larger than a mean length of grains of the second electrode portion in the first direction.

In some implementations, a semiconductor device may include a first gate electrode and a second gate electrode, which are spaced apart from each other in a first direction, a channel structure between the first gate electrode and the second gate electrode, a first gate insulating layer between the first gate electrode and the channel structure, and a second gate insulating layer between the second gate electrode and the channel structure. Each of the first and second gate electrodes may include a first electrode portion and a second electrode portion on the first electrode portion, and the first electrode portion may include a lower portion having an increasing width as a level increases and an upper portion having a decreasing width as a level increases.

### BRIEF DESCRIPTION OF THE DRAWINGS

FIG. 1A is a plan view illustrating an example of a semiconductor device.

FIG. 1B is an example sectional view taken along a line A-A′ of FIG. 1A.

FIG. 1C is an example enlarged view illustrating a portion ‘E1’ of FIG. 1B.

FIG. 1D is an example enlarged view illustrating a portion ‘E2’ of FIG. 1C.

FIGS. 2A, 2B, 2C, 2D, 2E, and 2F are sectional views illustrating an example of a method of fabricating a semiconductor device.

FIG. 3 is a plan view illustrating an example of a semiconductor device.

FIG. 4 is a sectional view illustrating an example of a semiconductor device.

FIG. 5 is a sectional view illustrating an example of a semiconductor device.

FIG. 6 is a sectional view illustrating an example of a semiconductor device.

FIG. 7 is a perspective view illustrating an example of a semiconductor device.

### DETAILED DESCRIPTION

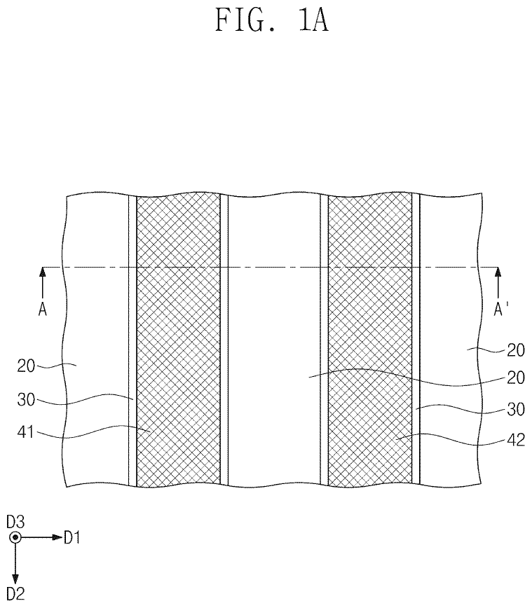

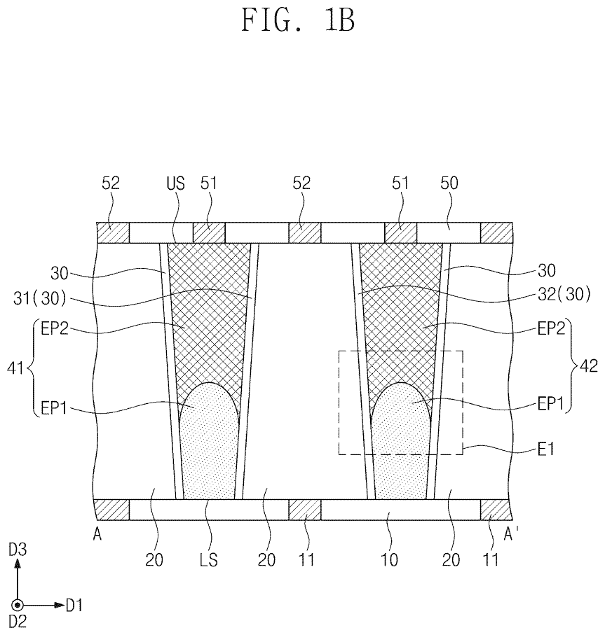

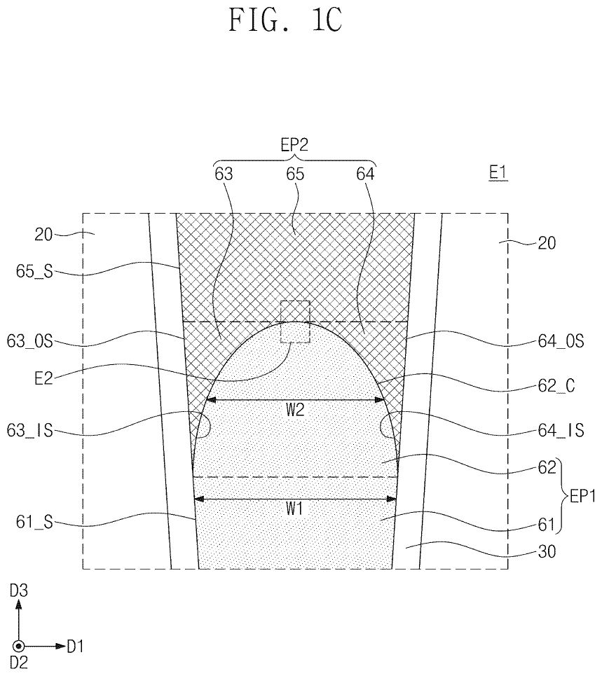

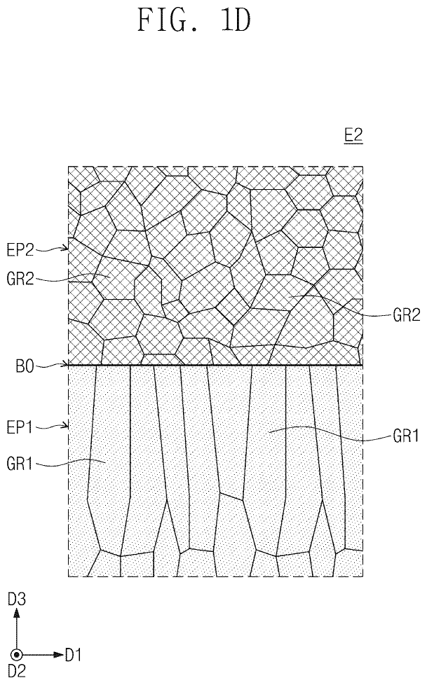

FIG. 1A is a plan view illustrating an example of a semiconductor device. FIG. 1B is an example sectional view taken along a line A-A′ of FIG. 1A. FIG. 1C is an example enlarged view illustrating a portion ‘E1’ of FIG. 1B. FIG. 1D is an example enlarged view illustrating a portion ‘E2’ of FIG. 1C.

Referring to FIGS. 1A and 1B, the semiconductor device may include a supporting insulating layer 10. The supporting insulating layer 10 may be a plate-shaped structure that is extended parallel to a plane defined by a first direction D1 and a second direction D2. The first and second directions D1 and D2 may not be parallel to each other. In some implementations, the first and second directions D1 and D2 may be horizontal directions that are orthogonal to each other. The supporting insulating layer 10 may include an insulating material. In some implementations, the supporting insulating layer 10 may include a plurality of insulating layers.

In some implementations, a substrate may be provided below the supporting insulating layer 10. The substrate may be a semiconductor substrate, an insulating substrate, a silicon-on-insulator (SOI) substrate, or a germanium-on-insulator (GOI) substrate.

In some implementations, first and second gate electrodes 41 and 42, channel structures 20, and gate insulating layers 30, which will be described below, may be provided on the substrate, without the supporting insulating layer 10.

A first conductive structure 11 may be provided in the supporting insulating layer 10. The first conductive structure 11 may include a conductive material. The first conductive structure 11 may include at least one of a conductive contact, a conductive line, or a conductive pad.

The channel structures 20, a first gate electrode 41, a second gate electrode 42, and the gate insulating layers 30 may be provided on the supporting insulating layer 10. The number of the channel structures 20, the number of the gate electrodes 41 and 42, and the number of the gate insulating layers 30 are not limited to the illustrated example.

The channel structure 20 may be formed of or include at least one of single-crystalline semiconductor materials, polycrystalline semiconductor materials, oxide semiconductor materials, or two-dimensional materials. The single crystalline semiconductor material may be single-crystalline silicon. The polycrystalline semiconductor material may be for example poly silicon. The oxide semiconductor material may be indium gallium zinc oxide (IGZO). For example, the two-dimensional material may be MoS₂, WS₂, MoSe₂, or WSe₂.

The channel structures 20 may be arranged to be spaced apart from each other in the first direction D1. The channel structure 20 may be extended in the second direction D2. A bottom surface of the channel structure 20 may be in contact with the supporting insulating layer 10 and the first conductive structure 11. The channel structure 20 may be electrically connected to the first conductive structure 11. A side surface of the channel structure 20 may be in contact with the gate insulating layer 30.

A width of the channel structure 20 in the first direction D1 may increase as a vertical level is lowered. In the present specification, the term “level” may mean a height from a bottom surface of the supporting insulating layer 10 in a third direction D3. The third direction D3 may not be parallel to the first and second directions D1 and D2. In some implementations, the third direction D3 may be a vertical direction that is orthogonal to the first and second directions D1 and D2.

The gate insulating layer 30 may be provided on the channel structure 20. A bottom surface of the gate insulating layer 30 may be in contact with a top surface of the supporting insulating layer 10. A side surface of the gate insulating layer 30 may be in contact with the gate electrode 41 or 42 or the channel structure 20. The gate insulating layer 30 may include an insulating material. In some implementations, the gate insulating layer 30 may be formed of or include an oxide material.

The gate electrode 41 or 42 may be provided on the gate insulating layer 30. The channel structure 20 and the gate insulating layers 30 may be provided between the first gate electrode 41 and the second gate electrode 42. The gate insulating layers 30 may include a first gate insulating layer 31 and a second gate insulating layer 32 between the first gate electrode 41 and the second gate electrode 42. The channel structure 20 may be provided between the first gate insulating layer 31 and the second gate insulating layer 32.

The gate electrodes 41 and 42 may be extended in the second direction D2. The gate electrodes 41 and 42 may be arranged to be spaced apart from each other in the first direction D1. A width of the gate electrode 41 or 42 in the first direction D1 may decrease as a vertical level is lowered. The gate electrode 41 or 42 may be spaced apart from the channel structure 20 in the first direction D1 by the gate insulating layer 30. In some implementations, a length of the gate electrode 41 or 42 in the second direction D2 may be larger than a length of the channel structure 20 in the second direction D2.

The gate electrode 41 or 42 may include a first electrode portion EP1 and a second electrode portion EP2. The second electrode portion EP2 may be provided on the first electrode portion EP1. A width of the first electrode portion EP1 in the first direction D1 may be smaller than a width of the second electrode portion EP2 in the first direction D1. The first and second electrode portions EP1 and EP2 may be provided on the gate insulating layer 30. The first and second electrode portions EP1 and EP2 may be in contact with a side surface of the gate insulating layer 30. In some implementations, a length of each of the first and second electrode portions EP1 and EP2 in the third direction D3 may range from 10 Å to 600 Å.

In some implementations, the first and second electrode portions EP1 and EP2 may include the same conductive material. As an example, the first and second electrode portions EP1 and EP2 may be formed of or include at least one of TiN, TiSiN, TiAlC, Mo, W, Ta, TaN, LaN, Al, Cu, or Ru. In some implementations, the first and second electrode portions EP1 and EP2 may be formed of or include different conductive materials from each other.

A bottom surface LS of the gate electrode 41 or 42 may be in contact with a top surface of the supporting insulating layer 10. A top surface US of the gate electrode 41 or 42 may be in contact with a capping insulating layer 50 and a second conductive structure 51, which will be described below. The bottom and top surfaces LS and US of the gate electrode 41 or 42 may be spaced apart from each other in the third direction D3. A distance between the bottom and top surfaces LS and US of the gate electrode 41 or 42 in the third direction D3 may be a height of the gate electrode 41 or 42 in the third direction D3. A width of the gate electrode 41 or 42 in the first direction D1 may increase as a distance from the bottom surface LS increases in a direction toward the top surface US. The bottom surface LS of the gate electrode 41 or 42 may be a bottom surface of the first electrode portion EP1. The top surface US of the gate electrode 41 or 42 may be a top surface of the second electrode portion EP2.

The capping insulating layer 50 may be provided on the channel structures 20, the gate insulating layers 30, and the gate electrodes 41 and 42. The capping insulating layer 50 may include an insulating material. In some implementations, the capping insulating layer 50 may include a plurality of insulating layers.

Second conductive structures 51 and third conductive structures 52 may be provided in the capping insulating layer 50. A bottom surface of the second conductive structure 51 may be in contact with the top surface US of the gate electrode 41 or 42. The second conductive structure 51 may be electrically connected to the gate electrode 41 or 42. A bottom surface of the third conductive structure 52 may be in contact with a top surface of the channel structure 20. The third conductive structure 52 may be electrically connected to the channel structure 20. Each of the second and third conductive structures 51 and 52 may include at least one of a conductive contact, a conductive line, or a conductive pad.

The first and third conductive structures 11 and 52 may not be limited to the illustrated structure and may have various structures, which are electrically connected to the channel structure 20. In some implementations, one of the first and third conductive structures 11 and 52 may be omitted.

The second conductive structure 51 may not be limited to the illustrated structure and may have various structures, which are electrically connected to the gate electrode 41 or 42. In some implementations, a conductive structure, which is electrically connected to the gate electrode 41 or 42, may be provided in the supporting insulating layer 10.

Referring to FIG. 1C, the first electrode portion EP1 may include a lower portion 61 and an upper portion 62. A width W1 of the lower portion 61 of the first electrode portion EP1 in the first direction D1 may increase as a vertical level increases. A width W2 of the upper portion 62 of the first electrode portion EP1 in the first direction D1 may decrease as a vertical level increases. A side surface 61_S of the lower portion 61 of the first electrode portion EP1 may be in contact with a side surface of the gate insulating layer 30. The upper portion 62 of the first electrode portion EP1 may be spaced apart from the gate insulating layer 30.

The second electrode portion EP2 may include a first lower portion 63, a second lower portion 64, and an upper portion 65. Widths of the first lower portion 63, the second lower portion 64, and the upper portion 65 of the second electrode portion EP2 in the first direction D1 may increase as a vertical level increases. An outer side surface 63_OS of the first lower portion 63 of the second electrode portion EP2, an outer side surface 64_OS of the second lower portion 64 of the second electrode portion EP2, and a side surface 65_S of the upper portion 65 of the second electrode portion EP2 may be in contact with the side surface of the gate insulating layer 30. The first and second lower portions 63 and 64 may be connected to the upper portion 65.

The upper portion 62 of the first electrode portion EP1 may be disposed between first and second lower portions 63 and 64 of the second electrode portion EP2. The upper portion 62 of the first electrode portion EP1 may be provided at the same level as the first and second lower portions 63 and 64 of the second electrode portion EP2. Each of the first and second lower portions 63 and 64 of the second electrode portion EP2 may be provided between the upper portion 62 of the first electrode portion EP1 and the gate insulating layer 30.

In some implementations, a length of the upper portion 62 of the first electrode portion EP1 in the third direction D3 may be substantially equal to a length of the first and second lower portions 63 and 64 of the second electrode portion EP2 in the third direction D3. In some implementations, a length of one of the first and second lower portions 63 and 64 of the second electrode portion EP2 in the third direction D3 may be equal to the length of the upper portion 62 of the first electrode portion EP1 in the third direction D3, and a length of the other of the first and second lower portions 63 and 64 of the second electrode portion EP2 in the third direction D3 may be smaller than the length of the upper portion 62 of the first electrode portion EP1 in the third direction D3.

A level of the uppermost portion of the upper portion 62 of the first electrode portion EP1 may be equal to a level of a boundary between the first lower portion 63 and the upper portion 65 of the second electrode portion EP2. The level of the uppermost portion of the upper portion 62 of the first electrode portion EP1 may be equal to a level of a boundary between the second lower portion 64 and the upper portion 65 of the second electrode portion EP2.

An inner side surface 63_IS of the first lower portion 63 of the second electrode portion EP2 may be in contact with the upper portion 62 of the first electrode portion EP1. The inner side surface 63_IS of the first lower portion 63 of the second electrode portion EP2 may have a curved shape. An inner side surface 64_IS of the second lower portion 64 of the second electrode portion EP2 may be in contact with the upper portion 62 of the first electrode portion EP1. The inner side surface 64_IS of the second lower portion 64 of the second electrode portion EP2 may have a curved shape.

The upper portion 62 of the first electrode portion EP1 may include a curved surface 62_C, which is in contact with the inner side surface 63_IS of the first lower portion 63 of the second electrode portion EP2 and the inner side surface 64_IS of the second lower portion 64 of the second electrode portion EP2. The curved surface 62_C of the upper portion 62 of the first electrode portion EP1 may be convex toward the second electrode portion EP2.

The side surface 61_S of the lower portion 61 of the first electrode portion EP1, the outer side surface 63_OS of the first lower portion 63 of the second electrode portion EP2, and the side surface 65_S of the upper portion 65 of the second electrode portion EP2 may be coplanar with each other. The side surface 61_S of the lower portion 61 of the first electrode portion EP1, the outer side surface 64_OS of the second lower portion 64 of the second electrode portion EP2, and the side surface 65_S of the upper portion 65 of the second electrode portion EP2 may be coplanar with each other.

Referring to FIG. 1D, a boundary BO between the first electrode portion EP1 and the second electrode portion EP2 may be defined. A density of a grain boundary in the boundary BO may be higher than a density of a grain boundary in the first electrode portion EP1 and a density of a grain boundary in the second electrode portion EP2.

A shape of grains GR1 of the first electrode portion EP1 may be different from a shape of grains GR2 of the second electrode portion EP2. A length of the grain GR1 of the first electrode portion EP1 may be larger in the third direction D3 than in the first direction D1.

A mean length of the grains GR1 of the first electrode portion EP1 in the third direction D3 may be larger than a mean length of the grains GR1 of the first electrode portion EP1 in the first direction D1. In some implementations, a mean length of the grains GR1 of the first electrode portion EP1 in the vertical direction may be larger than a mean length of the grains GR1 of the first electrode portion EP1 in the horizontal direction.

The mean length of the grains GR1 of the first electrode portion EP1 in the third direction D3 may be larger than a mean length of the grains GR2 of the second electrode portion EP2 in the first direction D1. The mean length of the grains GR1 of the first electrode portion EP1 in the third direction D3 may be larger than a mean length of the grains GR2 of the second electrode portion EP2 in the third direction D3.

In the semiconductor device, since the gate electrode 41 or 42 includes the first and second electrode portions EP1 and EP2, a seam or void may not be formed in the gate electrode 41 or 42. Thus, a cutting failure of the gate electrode 41 or 42 may be improved, and the reliability of the gate electrode 41 or 42 may be improved.

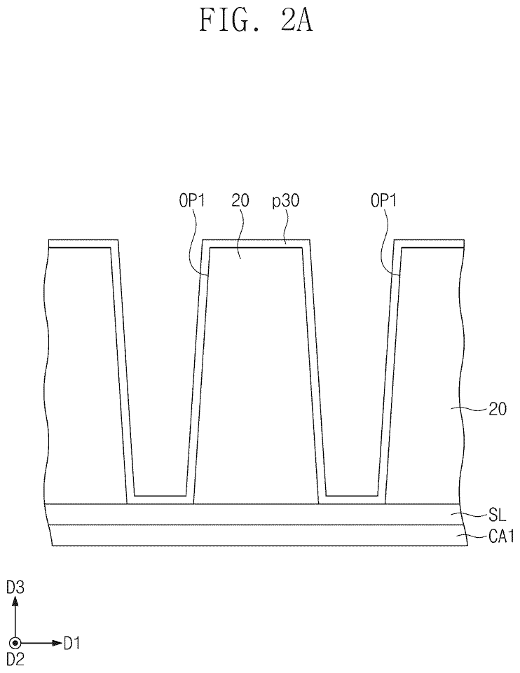

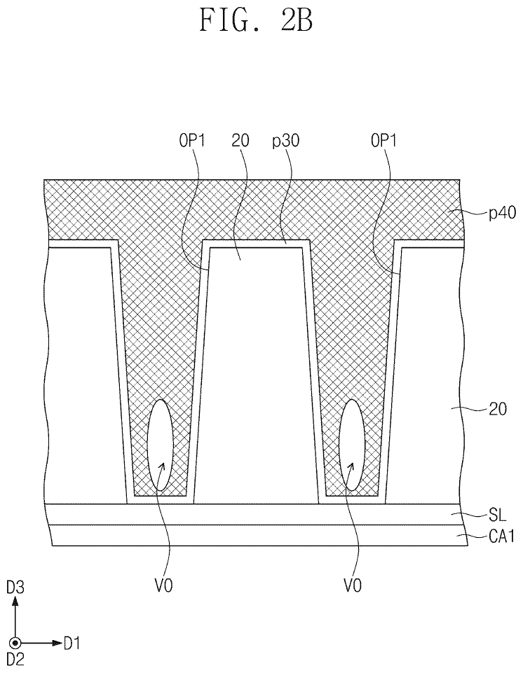

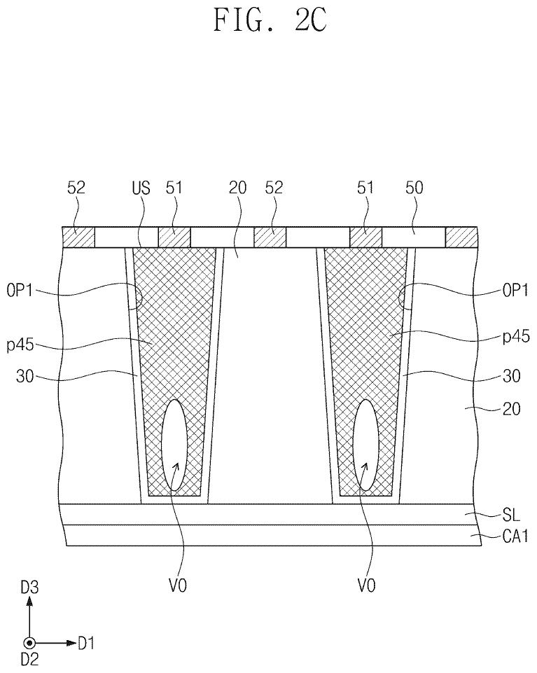

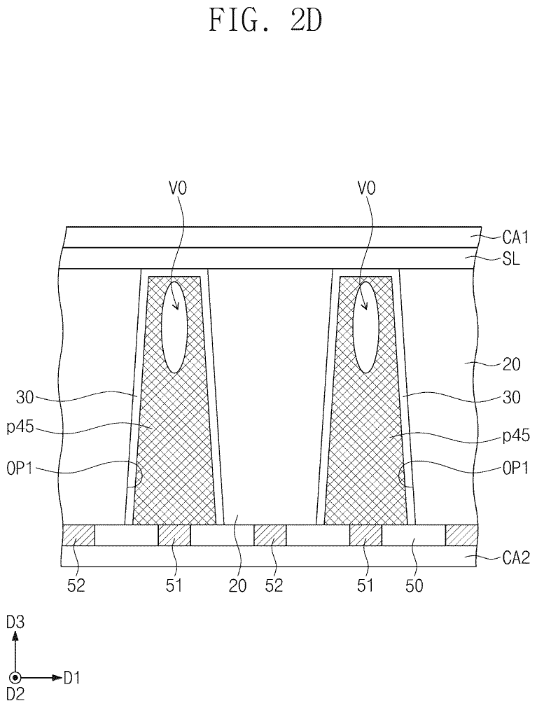

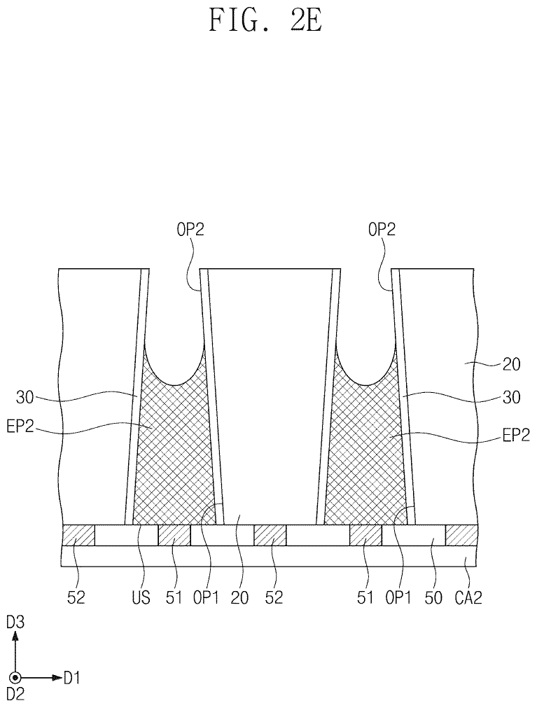

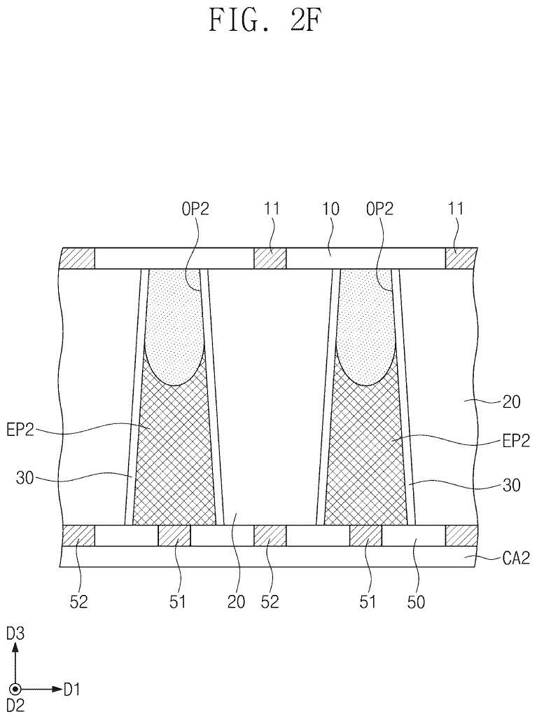

FIGS. 2A, 2B, 2C, 2D, 2E, and 2F are sectional views illustrating an example of a method of fabricating a semiconductor device.

Referring to FIG. 2A, a first carrier substrate CA1 and a sacrificial layer SL on the first carrier substrate CA1 may be provided. In some implementations, the sacrificial layer SL may include an insulating material.

The channel structures 20 and a preliminary gate insulating layer p30 may be formed on the sacrificial layer SL. The formation of the channel structures 20 and the preliminary gate insulating layer p30 may include forming a preliminary channel layer on the sacrificial layer SL, etching the preliminary channel layer to form the channel structures 20, and conformally forming the preliminary gate insulating layer p30 on the channel structures 20 and the sacrificial layer SL.

The preliminary channel layer may be etched to form a plurality of channel structures 20, which are separated from each other. As a result of the etching of the preliminary channel layer, first openings OP1 may be formed. The first opening OP1 may be defined by side surfaces of the channel structures 20 and a top surface of the sacrificial layer SL. Empty spaces between the channel structures 20 may be defined as the first openings OP1.

The preliminary gate insulating layer p30 may be provided to fill a portion of the first opening OP1. The preliminary gate insulating layer p30 may include an insulating material. In some implementations, the preliminary gate insulating layer p30 may be formed of or include an oxide material.

In some implementations, the channel structures 20 and the preliminary gate insulating layers p30 may be formed on the first carrier substrate CA1, without the sacrificial layer SL.

Referring to FIG. 2B, a gate electrode layer p40 may be formed. The gate electrode layer p40 may be formed through a conformal deposition process. In some implementations, the gate electrode layer p40 may be formed by a conformal CVD process or a conformal ALD process. The gate electrode layer p40 may be provided to fill the first openings OP1.

The gate electrode layer p40 may be formed on the preliminary gate insulating layers p30. A void VO may be formed in the gate electrode layer p40. The gate electrode layer p40 may include a conductive material. For example, the gate electrode layer p40 may be formed of or include at least one of TiN, TiSiN, TiAlC, Mo, W, Ta, TaN, LaN, Al, Cu, or Ru.

Referring to FIG. 2C, an upper portion of the gate electrode layer p40 and an upper portion of the preliminary gate insulating layer p30 may be removed. The upper portion of the gate electrode layer p40 and the upper portion of the preliminary gate insulating layer p30 may be formed by, for example, at least one of a chemical mechanical polishing (CMP) process or an etch-back process. An upper portion of the gate electrode layer p40 may be placed at a level higher than the channel structure 20. The upper portion of the preliminary gate insulating layer p30 may be placed at a level higher than the channel structure 20. The upper portion of the gate electrode layer p40 may be placed at a level higher than the first opening OP1. The upper portion of the preliminary gate insulating layer p30 may be placed at a level higher than the first opening OP1.

The upper portion of the gate electrode layer p40 may be removed, and the gate electrode layer p40 may be divided into preliminary gate electrodes p45. Since the upper portion of the preliminary gate insulating layer p30 is removed, the preliminary gate insulating layer p30 may be divided into the gate insulating layers 30. The preliminary gate electrode p45, which is a portion of the gate electrode layer p40, may be left in the first opening OP1. A portion of the preliminary gate insulating layer p30 may be left in the first opening OP1 and may be defined as the gate insulating layer 30.

The capping insulating layer 50 may be formed on the channel structures 20, the gate insulating layers 30, and the preliminary gate electrodes p45. The second conductive structures 51 and the third conductive structures 52 may be formed in the capping insulating layer 50.

Referring to FIG. 2D, a second carrier substrate CA2 may be formed on the capping insulating layer 50. The second carrier substrate CA2 may be inverted.

Referring to FIG. 2E, the first carrier substrate CA1 and the sacrificial layer SL may be removed. As a result of the removal of the first carrier substrate CA1 and the sacrificial layer SL, the preliminary gate electrodes p45 may be exposed to the outside. The exposed portion of the preliminary gate electrode p45 may be removed. For example, a portion of the preliminary gate electrode p45 may be removed through a selective etching process. Since the portion of the preliminary gate electrode p45 is removed, the void VO in the preliminary gate electrode p45 may be removed. The partially-removed preliminary gate electrode p45 may be defined as the second electrode portion EP2.

As a result of the partial removal of the preliminary gate electrode p45, a portion of the first opening OP1 may be opened. The opened portion of the first opening OP1 may be defined as a second opening OP2. The second opening OP2 may be defined by the gate insulating layer 30 and the second electrode portion EP2. A width of the second opening OP2 in the first direction D1 may be smaller than a width of the second electrode portion EP2 in the first direction D1.

Referring to FIG. 2F, the first electrode portions EP1 may be formed. The first electrode portion EP1 may be formed by a selective deposition process, in which the second electrode portion EP2 is used as a seed. In some implementations, the first electrode portion EP1 may be selectively formed on the second electrode portion EP2 through a selective CVD process or a selective ALD process. Since the first electrode portion EP1 is formed through the selective deposition process, the grains of the first electrode portion EP1 may have a shape that is different from the grains of the second electrode portion EP2. The first electrode portion EP1 may fill the second opening OP2.

In some implementations, a process of removing an oxide layer of the second electrode portion EP2 may be performed, before the formation of the first electrode portion EP1.

The supporting insulating layer 10 may be formed on the channel structures 20, the first electrode portions EP1, and the gate insulating layers 30. The first conductive structures 11 may be formed in the supporting insulating layer 10.

Referring to FIGS. 1A and 1B, the second carrier substrate CA2 may be inverted. Thereafter, a second carrier substrate CA may be removed.

In a method of fabricating a semiconductor device, since the first electrode portion EP1 is formed after the partial removal of the preliminary gate electrode p45, a void or seam may not be formed in the gate electrode 41 or 42. Accordingly, it may be possible to improve the reliability characteristics of the gate electrode 41 or 42.

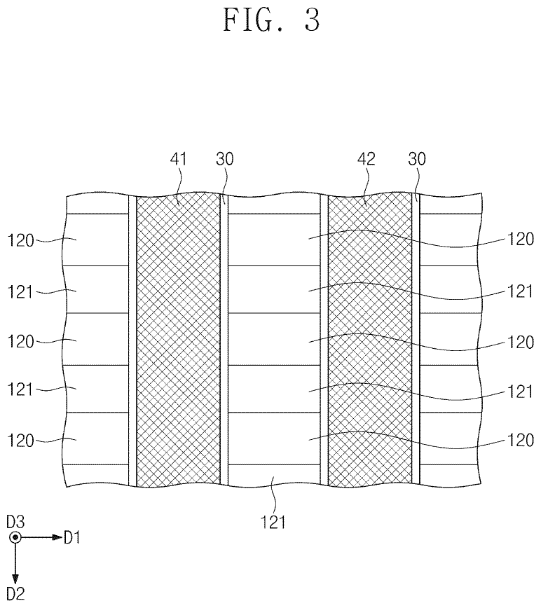

FIG. 3 is a plan view illustrating an example of a semiconductor device. The semiconductor device of FIG. 3 may have similar features to the semiconductor device of FIGS. 1A to 1D, except for the features to be described below.

Referring to FIG. 3, the semiconductor device may include channel insulating layers 121. A channel structure 120 may be provided between the channel insulating layers 121, which are adjacent to each other in the second direction D2. The channel insulating layer 121 may be formed of or include an insulating material.

The channel structures 120 and the channel insulating layers 121 may be provided between the first gate electrode 41 and the second gate electrode 42. The channel structures 120 and the channel insulating layers 121 between the first gate electrode 41 and the second gate electrode 42 may be alternately arranged in the second direction D2.

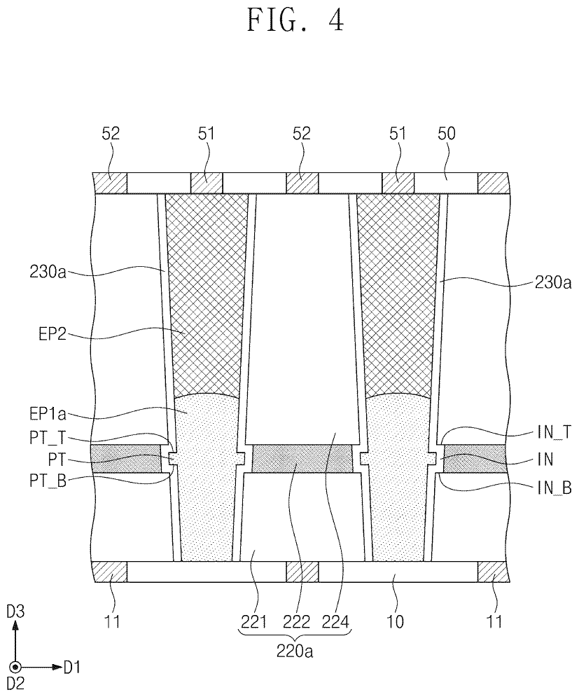

FIG. 4 is a sectional view illustrating an example of a semiconductor device. The semiconductor device of FIG. 4 may have similar features to the semiconductor device of FIGS. 1A to 1D, except for the features to be described below.

Referring to FIG. 4, a channel structure 220a may include a first channel layer 221, an interlayer insulating layer 222 on the first channel layer 221, and a second channel layer 224 on the interlayer insulating layer 222.

As a vertical level is lowered, each of the interlayer insulating layer 222, the first channel layer 221, and the second channel layer 224 may be provided to have an increasing width in the first direction D1. The largest width of the interlayer insulating layer 222 in the first direction D1 may be smaller than the smallest width of the first channel layer 221 in the first direction D1. The smallest width of the interlayer insulating layer 222 in the first direction D1 may be smaller than the largest width of the second channel layer 224 in the first direction D1.

The first and second channel layers 221 and 224 may include at least one of single-crystalline semiconductor materials, polycrystalline semiconductor materials, oxide semiconductor materials, or two-dimensional materials. The interlayer insulating layer 222 may include an insulating material. In some implementations, the interlayer insulating layer 222 may be formed of or include at least one of oxide materials or nitride materials. In some implementations, a connection conductive pattern electrically connecting the first channel layer 221 to the second channel layer 224 may be provided.

The first electrode portion EP1a may include a protruding portion PT, which is placed at the same level as the interlayer insulating layer 222. The protruding portion PT may have a top surface PT_T and a bottom surface PT_B, which are in contact with a gate insulating layer 230a.

The gate insulating layer 230a may include an intervening portion IN between the first and second channel layers 221 and 224. A top surface IN_T of the intervening portion IN may be in contact with a bottom surface of the second channel layer 224. A bottom surface IN_B of the intervening portion IN may be in contact with a top surface of the first channel layer 221.

In the semiconductor device, the channel structure 220a may include the interlayer insulating layer 222. Here, an etch rate of the interlayer insulating layer 222 may be relatively high in a process of forming the channel structures 220a, and a space between the interlayer insulating layers 222 may be relatively wide. Although the space between the interlayer insulating layers 222 is relatively wide, a void or a seam may not be formed in the gate electrode, because the first electrode portion EP1a is formed separately.

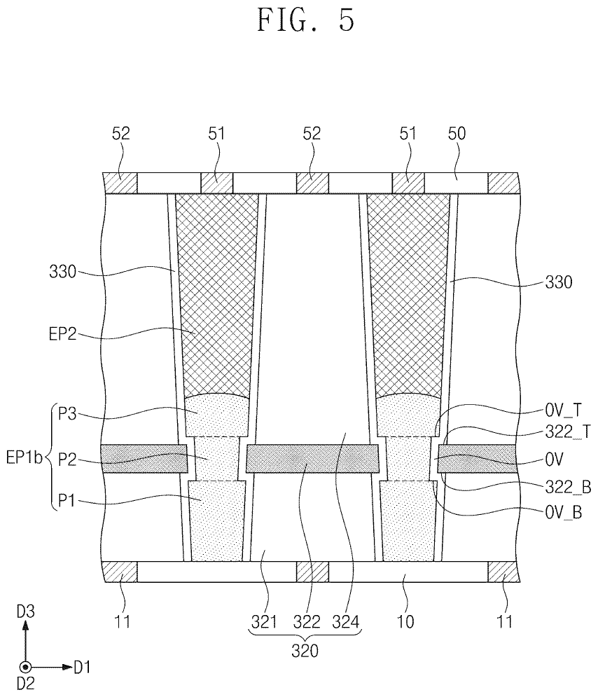

FIG. 5 is a sectional view illustrating an example of a semiconductor device. The semiconductor device of FIG. 5 may have similar features to the semiconductor device of FIGS. 1A to 1D, except for the features to be described below.

Referring to FIG. 5, a channel structure 320 may include a first channel layer 321, an interlayer insulating layer 322 on the first channel layer 321, and a second channel layer 324 on the interlayer insulating layer 322.

A width of each of the interlayer insulating layer 322, the first channel layer 321, and the second channel layer 324 in the first direction D1 may increases as a vertical level decreases. The largest width of the interlayer insulating layer 322 in the first direction D1 may be larger than the smallest width of the first channel layer 321 in the first direction D1. The smallest width of the interlayer insulating layer 322 in the first direction D1 may be larger than the largest width of the second channel layer 324 in the first direction D1.

A portion of a top surface 322_T of the interlayer insulating layer 322 may be in contact with a gate insulating layer 330. A portion of a bottom surface 322_B of the interlayer insulating layer 322 may be in contact with the gate insulating layer 330.

The first electrode portion EP1b may include a first portion P1, a second portion P2 on the first portion P1, and a third portion P3 on the second portion P2. The second portion P2 of the first electrode portion EP1b may be disposed at the same level as the interlayer insulating layer 322. The gate insulating layer 330 may include an overlapping portion OV, which is overlapped with the first and third portions P1 and P3 of the first electrode portion EP1b in the third direction D3.

A top surface OV_T of the overlapping portion OV may be in contact with a bottom surface of the third portion P3 of the first electrode portion EP1b. A bottom surface OV_B of the overlapping portion OV may be in contact with a top surface of the first portion P1 of the first electrode portion EP1b.

In the semiconductor device, the channel structure 320 may include the interlayer insulating layer 322. Here, an etch rate of the interlayer insulating layer 322 may be relatively low in a process of forming the channel structures 320, and a space between the interlayer insulating layers 322 may be relatively narrow. Although the space between the interlayer insulating layers 322 is relatively narrow, a void or a seam may not be formed in the gate electrode, because the first electrode portion EP1b is formed separately.

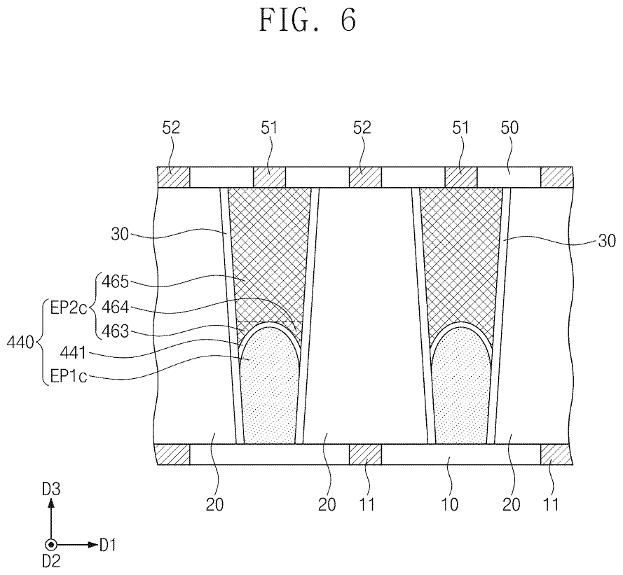

FIG. 6 is a sectional view illustrating an example of a semiconductor device. The semiconductor device of FIG. 6 may have similar features to the semiconductor device of FIGS. 1A to 1D, except for the features to be described below.

Referring to FIG. 6, a gate electrode 440 may include an oxide layer 441 between a first electrode portion EP1c and a second electrode portion EP2c. The oxide layer 441 may be in contact with the first electrode portion EP1c, the second electrode portion EP2c, and the gate insulating layer 30.

The oxide layer 441 may be formed of or include an oxide material. In some implementations, the second electrode portion EP2c may be oxidized to form the oxide layer 441. The second electrode portion EP2c may include a first lower portion 463, a second lower portion 464, and an upper portion 465. At least a portion of the oxide layer 441 may be provided between the first and second lower portions 463 and 464 of the second electrode portion EP2c.

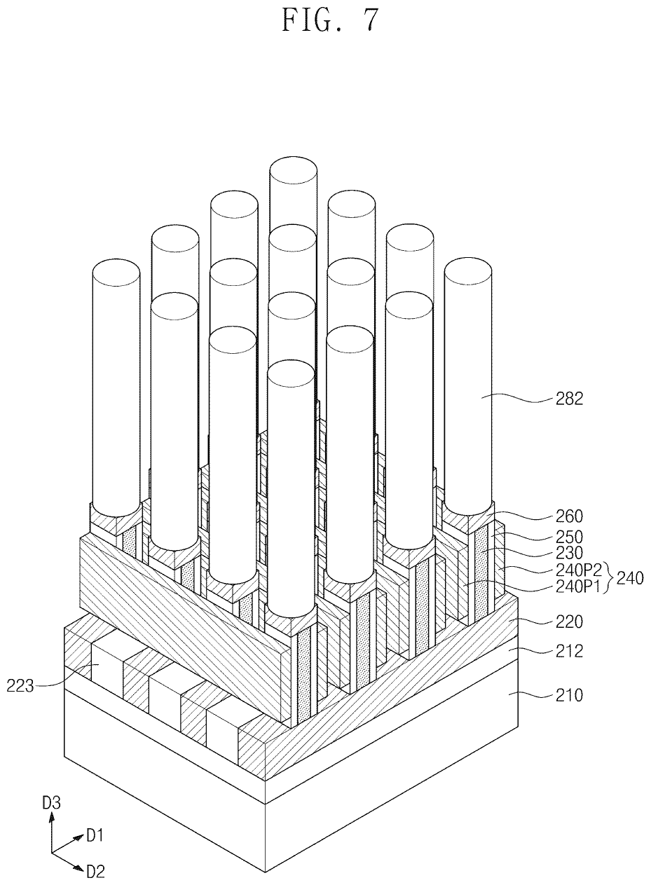

FIG. 7 is a perspective view illustrating an example of a semiconductor device.

Referring to FIG. 7, the semiconductor device may include a substrate 210, a plurality of conductive lines 220, a channel structure 230, a gate structure 240, a gate insulating layer 250, and a capacitor structure 282. The semiconductor device may be a memory device including a vertical channel transistor (VCT). In the vertical channel transistor, a channel length of the channel structure 230 may be defined in a direction normal to the top surface of the substrate 210.

A lower insulating layer 212 may be disposed on the substrate 210, and the conductive lines 220 may be disposed on the lower insulating layer 212 to be spaced apart from each other in the second direction D2 and may be extended in the first direction D1. A plurality of insulating structures 223 may be provided on the lower insulating layer 212 to fill spaces between the conductive lines 220. The insulating structures 223 may be extended in the first direction D1, and top surfaces of the insulating structures 223 may be disposed at the same level as top surfaces of the conductive lines 220. The conductive lines 220 may be used as bit lines of the semiconductor device.

In some implementations, the conductive lines 220 may be formed of or include at least one of doped polysilicon, metal, conductive metal nitride, conductive metal silicide, conductive metal oxide, or combinations thereof. For example, the conductive lines 220 may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited to this example. The conductive lines 220 may have a single- or multi-layered structure including at least one of the materials enumerated above. In some implementations, the conductive lines 220 may be formed of or include at least one of two-dimensional semiconductor material (e.g., graphene, carbon nanotube, or combinations thereof).

The channel structures 230 may be arranged on the conductive lines 220 and may be spaced apart from each other in the first and second directions D1 and D2 to form a matrix shape. The channel structure 230 may have a first width in the second direction D2 and a first height in the third direction D3, and here, the first height may be larger than the first width. For example, the first height may be about 2 to 10 times the first width, but the present disclosure is not limited to this example. A bottom portion of the channel structure 230 may serve as a first source/drain region, an upper portion of the channel structure 230 may serve as a second source/drain region, and a portion of the channel structure 230 between the first and second source/drain regions may serve as a channel region.

In some implementations, the channel structure 230 may be formed of or include at least one of oxide semiconductor materials (e.g., InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof). The channel structure 230 may have a single- or multi-layered structure, which is formed of or includes at least one of the oxide semiconductor materials. In some implementations, the channel structure 230 may have a band gap energy that is greater than a band gap energy of silicon. For example, the channel structure 230 may have a band gap energy of about 1.5 eV to 5.6 eV. For example, the channel structure 230 may have an optimized channel performance, when it has a band gap energy of about 2.0 eV to 4.0 eV. For example, the channel structure 230 may have polycrystalline or amorphous, but the present disclosure is not limited to this example. In some implementations, the channel structure 230 may be formed of or include at least one of two-dimensional semiconductor materials (e.g., graphene, carbon nanotube, or combinations thereof).

The gate structure 240 may be provided on opposite side surfaces of the channel structure 230 and may be extended in the second direction D2. The gate structure 240 may include a first gate electrode 240P1, which faces a first side surface of the channel structure 230, and a second gate electrode 240P2, which faces a second side surface of the channel structure 230 opposite to the first side surface. Since one channel structure 230 is disposed between the first gate electrode 240P1 and the second gate electrode 240P2, the semiconductor device may have a dual gate transistor structure. However, the present disclosure is not limited to this example, and the gate structure 240 may be configured to have only the first gate electrode 240P1, which faces the first side surface of the channel structure 230, without the second gate electrode 240P2. In this case, the transistor of the semiconductor device may have a single gate transistor structure.

The first gate electrode 240P1 and the second gate electrode 240P2 may be formed of or include at least one of doped polysilicon, metal, conductive metal nitride, conductive metal silicide, conductive metal oxide, or combinations thereof. For example, the first gate electrode 240P1 and the second gate electrode 240P2 may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited to this example.

In some implementations, the first gate electrode 240P1 and the second gate electrode 240P2 may have a structure similar to the gate electrode of FIG. 1A to 1D, 4, 5, or 6.

The gate insulating layer 250 may enclose a side surface of the channel structure 230 and may be interposed between the channel structure 230 and the gate structure 240. For example, the entire side surface of the channel structure 230 may be enclosed by the gate insulating layer 250, and a portion of a side surface of the gate structure 240 may be in contact with the gate insulating layer 250. In some implementations, the gate insulating layer 250 may be extended in an extension direction of the gate structure 240, and only two of the side surfaces of the channel structure 230, which face the gate structure 240, may be in contact with the gate insulating layer 250.

In some implementations, the gate insulating layer 250 may be formed of silicon oxide, silicon oxynitride, a high-k dielectric material, which has a higher dielectric constant than the silicon oxide, or combinations thereof. The high-k dielectric material may be formed of or include metal oxide or metal oxynitride. For example, the high-k dielectric material, which is used as the gate insulating layer 250, may include HfO₂, HfSiO, HfSiON, HfTaO, HfTiO, HfZrO, ZrO₂, Al₂O₃, or combinations thereof, but the present disclosure is not limited to this example.

A capacitor contact structure 260 may be disposed on the channel structure 230. The capacitor contact structure 260 may be vertically overlapped with the channel structure 230 and may be arranged in the first and second directions D1 and D2 to form a matrix shape. The capacitor contact structure 260 may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited to this example.

The capacitor structure 282 may be provided on the capacitor contact structure 260. In some implementations, the capacitor structure 282 may include a lower electrode, an upper electrode, and a capacitor insulating layer.

In a semiconductor device, a gate electrode may include a first electrode portion and a second electrode portion, and a seam or a void may not be formed in the gate electrode. Thus, the reliability of the gate electrode may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations of the present disclosure have been shown and described, it will be understood by one of ordinary skill in the art that variations in form and detail may be made therein without departing from the spirit and scope of the attached claims.

What is claimed is:

1. A semiconductor device, comprising:
a channel structure;
a gate insulating layer on the channel structure; and
a first electrode portion and a second electrode portion, the first electrode portion and the second electrode portion being on the gate insulating layer,
wherein the first electrode portion comprises a lower portion and an upper portion, the lower portion contacts the gate insulating layer, and the upper portion is spaced apart from the gate insulating layer,
wherein the second electrode portion comprises a first lower portion and a second lower portion,
wherein the first lower portion of the second electrode portion is between the gate insulating layer and the upper portion of the first electrode portion, and
wherein the upper portion of the first electrode portion is between the first lower portion and the second lower portions of the second electrode portion.

2. The semiconductor device of claim 1, wherein the upper portion of the first electrode portion comprises a curved surface contacting the second electrode portion.

3. The semiconductor device of claim 2, wherein the curved surface of the first electrode portion is convex toward the second electrode portion.

4. The semiconductor device of claim 1, wherein a first width of the first lower portion of the second electrode portion decreases as a vertical level of the first width decreases, and a second width of the second lower portion of the second electrode portion decreases as a vertical level of the second width decreases.

5. The semiconductor device of claim 1, comprising an oxide layer between the first electrode portion and the second electrode portion.

6. The semiconductor device of claim 1, wherein the channel structure comprises:
a first channel layer;
a second channel layer; and
an interlayer insulating layer between the first and second channel layers,
wherein the first electrode portion comprises a protruding portion, the protruding portion disposed at a same level as the interlayer insulating layer, and
wherein a top surface and a bottom surface of the protruding portion contact the gate insulating layer.

7. The semiconductor device of claim 1, wherein the channel structure comprises:
a first channel layer;
a second channel layer; and
an interlayer insulating layer between the first and second channel layers,
wherein the gate insulating layer contacts a top surface and a bottom surface of the interlayer insulating layer.

8. A semiconductor device, comprising:
a channel structure;
a first gate insulating layer on the channel structure; and
a first gate electrode on the first gate insulating layer,
wherein the first gate electrode comprises a top surface and a bottom surface, and the top surface and the bottom surface are spaced apart from each other in a first direction,
wherein the first gate electrode comprises a first electrode portion and a second electrode portion, the first electrode portion and the second electrode portion being on the first electrode portion, and
wherein a mean length of grains of the first electrode portion in the first direction is larger than a mean length of grains of the second electrode portion in the first direction.

9. The semiconductor device of claim 8, wherein the channel structure and the first gate electrode are spaced apart from each other by the first gate insulating layer in a second direction, the second direction crossing the first direction, and
wherein a mean length of the grains of the first electrode portion in the second direction is smaller than the mean length of the grains of the first electrode portion in the first direction.

10. The semiconductor device of claim 8, wherein the channel structure and the first gate electrode are spaced apart from each other by the first gate insulating layer in a second direction, the second direction crossing the first direction, and
wherein a mean length of the grains of the second electrode portion in the second direction is smaller than the mean length of the grains of the first electrode portion in the first direction.

11. The semiconductor device of claim 8, wherein the channel structure and the first gate electrode are spaced apart from each other by the first gate insulating layer in a second direction, the second direction crossing the first direction, and
wherein a width of the second electrode portion in the second direction is larger than a width of the first electrode portion in the second direction.

12. The semiconductor device of claim 8, wherein the top surface of the first gate electrode is a top surface of the second electrode portion,
wherein the bottom surface of the first gate electrode is a bottom surface of the first electrode portion, and
wherein a width of the first gate electrode increases as a distance from the bottom surface of the first gate electrode increases in a direction toward the top surface of the first gate electrode.

13. The semiconductor device of claim 8, comprising:
a second gate insulating layer on the channel structure; and
a second gate electrode on the second gate insulating layer,
wherein the channel structure, the first gate insulating layer, and the second gate insulating layer are disposed between the first gate electrode and the second gate electrode.

14. The semiconductor device of claim 8, wherein the second electrode portion comprises a first lower portion, a second lower portion, and an upper portion, the upper portion being connected to the first lower portion and the second lower portion, and
wherein the first electrode portion comprises an upper portion between the first lower portion and the second lower portion of the second electrode portion.

15. The semiconductor device of claim 14, wherein a width of the upper portion of the first electrode portion decreases as a vertical level of the width increases, and
wherein a first width of the first lower portion of the second electrode portion increases as a vertical level of the first width increases, and a second width of the second lower portion of the second electrode portion increases as a vertical level of the second width increases.

16. A semiconductor device, comprising:
a first gate electrode and a second gate electrode, wherein the first gate electrode and the second gate electrode are spaced apart from each other in a first direction;
a channel structure between the first gate electrode and the second gate electrode;
a first gate insulating layer between the first gate electrode and the channel structure; and
a second gate insulating layer between the second gate electrode and the channel structure,
wherein each gate electrode of the first gate electrode and the second gate electrode comprises a first electrode portion and a second electrode portion, the second electrode portion being on the first electrode portion, and
wherein the first electrode portion comprises a lower portion and an upper portion, a first width of the lower portion increases as a vertical level of the first width increases, and a second width of the upper portion increases as a vertical level of the second width increases.

17. The semiconductor device of claim 16, wherein a density of a grain boundary in a boundary between the first electrode portion and the second electrode portion is greater than a density of a grain boundary in the first electrode portion and a density of a grain boundary in the second electrode portion.

18. The semiconductor device of claim 16, wherein the second electrode portion comprises a first lower portion and a second lower portion, and the first lower portion and the second lower portion are located at a same level as the upper portion of the first electrode portion.

19. The semiconductor device of claim 18, wherein the upper portion of the first electrode portion is disposed between the first lower portion and the second lower portion of the second electrode portion.

20. The semiconductor device of claim 16, wherein a width of the channel structure decreases as a vertical level of the width of the channel structure increases.
